(19) United States
(12) Patent Application Publication
(10) Pub. No.: US 2026/0223633 A1
(43) Pub. Date: Jul. 30, 2026

(54) SEMICONDUCTOR WAFER PROCESSING WITH TEMPERATURE CONTROL AND BIAS POWERED PROCESS RING FOR EXTREME EDGE CONTROL

(71) Applicant: Applied Materials, Inc., Santa Clara, CA (US)

(72) Inventors: Yogananda SARODE VISHWANATH, Bangalore (IN); Anand KUMAR, Bangalore (IN)

(21) Appl. No.: 19/036,906

(22) Filed: Jan. 24, 2025

(51) Int. Cl. H01L 21/683; H01J 37/32

(52) U.S. Cl. CPC H10P 72/722; H01J 37/32642; H01J 37/32724; H01J 2237/2007

(57) ABSTRACT

Examples described herein generally related to a process kit for a semiconductor processing chamber. In one example, the process kit includes an edge ring having an inner diameter, a bottom surface and a top surface. The edge ring is configured to circumscribe a substrate in a semiconductor processing chamber. The process kit includes a insert ring positioned beneath the edge ring. The insert ring has an upper surface configured to contact the bottom surface of the edge ring. The insert ring has a body having a lower surface, an electrode disposed in the body, and a pin extending into the body through the lower surface coupled to the electrode. A conductive pin of the pin protrudes from the lower surface and is configured to couple to a power supply for the electrode.

### BACKGROUND

### Field

Examples described herein generally relate to a substrate processing apparatus, and more specifically to an improved apparatus for controlling a plasma edge profile for processing substrates.

### Description of the Related Art

As semiconductor technology nodes advanced with reduced size device geometries, substrate edge critical dimension uniformity requirements become more stringent and affect die yields. Commercial plasma reactors include multiple tunable knobs for controlling process uniformity across a substrate, such as, for example, temperature, gas flow, direct current (DC) power, and the like. Typically, in etch processes, silicon substrates are etched while electrostatically clamped to an electrostatic chuck.

During processing, a substrate resting on a substrate support may undergo a process that deposits material on the substrate and to remove, or etch, portions of the material from the substrate, often in succession or in alternating processes. It is typically beneficial to have uniform deposition and etching rates across the surface of the substrate. However, process non-uniformities often exist across the surface of the substrate and may be significant at the perimeter or edge of the substrate. These non-uniformities at the perimeter may be attributable to electric field termination affects and are sometimes referred to as edge effects. During deposition or etching, a process kit containing at least a deposition ring is sometimes provided to favorably influence uniformity at the substrate perimeter or edge.

Conventional process kits have relied on radio frequency (RF) coupling to control the edge profile of the plasma while processing. The conventional process kits additionally rely on moving the edge ring vertically to control the plasma profile along the substrate perimeter or edge. However, moving rings in the substrate support have been found to introduce particles into the chamber environment which can cause defects on the substrate. Thus, the high risk for particle contamination makes moving the ring for controlling the profile and tuning the plasma when substrate processing undesirable for next generation processing.

Accordingly, there is a need for an improved apparatus for a substrate processing.

### SUMMARY

Examples described herein generally related to a process kit for a semiconductor processing chamber. In one example, the process kit includes an edge ring having an inner diameter, a bottom surface and a top surface. The edge ring is configured to circumscribe a substrate in a semiconductor processing chamber. The process kit includes a powered insert ring positioned beneath the edge ring. The powered insert ring has an upper surface configured to contact the bottom surface of the edge ring. The powered insert ring has a body having a lower surface, an electrode disposed in the body, and a coupling mechanism extending into the body through the lower surface coupled to the electrode. A conductive pin of the coupling mechanism protrudes from the lower surface and is configured to couple to a power supply used to power the electrode.

In another example, a substrate support assembly is disclosed. The substrate support assembly includes an electrostatic chuck (ESC). The ESC has an ESC outer diameter, a substrate supporting surface and a bottom surface. The substrate support assembly has a powered cooling base. The powered cooling base has a cooling base outer diameter and an upper surface. A slot is formed in the upper surface of the powered cooling base near the cooling base outer diameter. The powered cooling base is configured to be coupled to a power supply. A process kit has an edge ring that includes an inner diameter, a bottom surface and a top surface. The edge ring is configured to circumscribe a substrate in a semiconductor processing chamber. The process kit includes a powered insert ring positioned below the edge ring. The powered insert ring has an upper surface configured to contact the bottom surface of the edge ring. The powered insert ring has a body having a lower surface, an electrode disposed in the body, and a coupling mechanism extending into the body through the lower surface coupled to the electrode. A conductive pin of the coupling mechanism protrudes from the lower surface and is coupled to the powered cooling base.

In another example, a substrate processing chamber is disclosed. The substrate processing chamber has a chamber body. The chamber body has a lid assembly, one or more sidewalls, and a chamber base. The lid assembly, one or more sidewalls and the chamber base collectively define a processing volume. A system controller is coupled to the chamber body and an edge ring power source. A substrate support assembly is disposed in the processing volume. The substrate support assembly includes an electrostatic chuck (ESC). The ESC has an ESC outer diameter, a substrate supporting surface and a bottom surface. The substrate support assembly has a powered cooling base. The powered cooling base has a cooling base outer diameter and an upper surface and a slot formed in the upper surface of the powered cooling base near the cooling base outer diameter. The powered cooling base is configured to be coupled to a power supply. A process kit has an edge ring having an inner diameter, a bottom surface and a top surface. The edge ring is configured to circumscribe a substrate in a semiconductor processing chamber. The process kit includes a powered insert ring positioned beneath the edge ring. The powered insert ring has an upper surface configured to contact the bottom surface of the edge ring. The powered insert ring has a body having a lower surface, an electrode disposed in the body, and a coupling mechanism extending into the body through the lower surface coupled to the electrode. A conductive pin of the coupling mechanism protrudes from the lower surface and is coupled to the powered cooling base.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is to be noted, however, that the appended drawings illustrate only typical examples of this disclosure and are therefore not to be considered limiting of its scope, for the disclosure may admit to other equally effective examples.

FIG. 1 is a cross sectional view of a processing chamber, according to one example.

FIG. 2A is enlarged partial cross sectional view of a portion of a substrate support assembly of FIG. 1, according to one example.

FIG. 2B is another enlarged partial cross sectional view of a portion of the substrate support assembly of FIG. 1, according to one example.

FIG. 3 illustrates a top perspective view of the powered insert ring shown in FIGS. 2A and 2B.

FIG. 4 illustrates a side perspective view of the powered insert ring shown in FIGS. 2A and 2B.

For clarity, identical reference numerals have been used, where applicable, to designate identical elements that are common between figures. Additionally, elements of one example may be advantageously adapted for utilization in other examples described herein.

### DETAILED DESCRIPTION

Examples of the disclosure generally include methods and apparatuses that improve etch rate uniformity across a surface of a substrate by controlling the shape of a plasma sheath formed across the substrate, such as a semiconductor wafer, during plasma processing. Examples of the disclosure include adjustment of one or more plasma processing variables and/or the adjustment of the configuration of process kit hardware that is in close proximity to a substrate and/or supports the substrate during processing. These adjustments allow the uniformity of the plasma sheath formed across the wafer surface can be controlled, thereby increasing wafer processing yield.

More specifically, the disclosure herein includes a processing chamber configuration that includes a cathode assembly. The cathode assembly having a cathode plate with a threaded connection coupled to a powered insert ring. The powered insert ring is configured to enable the biasing of an edge ring during processing. The biased edge ring can be used to adjust the shape of a plasma sheath formed across a substrate. In addition to this, a bottom face of the powered insert ring can include a plurality of pins. In one example, three pins extend below the powered insert ring and are configured to make a direct physical and electrical contact with a powered cooling base disposed thereunder. Thus, the new cathode configuration enables improved source power delivery to the edge ring through the cathode assembly with reduced particle contamination from component wear commonly present in conventional designs.

Furthermore, heat transfer shims are provided to enhance thermal coupling to the cooling base. The extended cooling base and thermal coupling helps maintain the temperature of the process kit to be similar to that of the ESC.

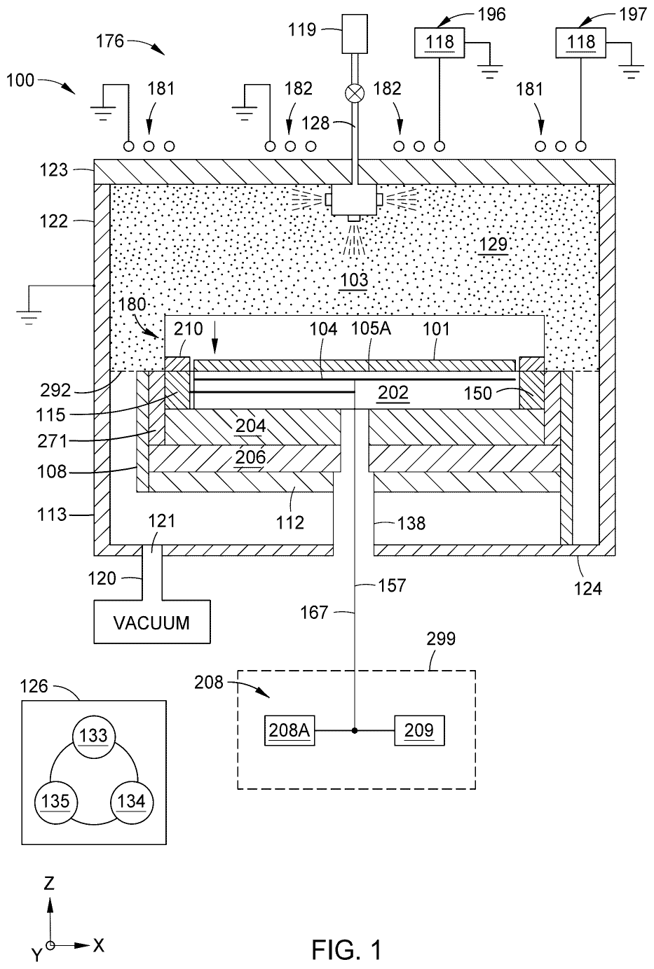

FIG. 1 is a cross sectional view of a processing chamber 100 having a RF powered insert ring 150, according to one example. As shown, the processing chamber 100 is an etch chamber suitable for etching a substrate, such as substrate 101. Examples of processing chambers that may be adapted to benefit from the disclosure are Sym3® Processing Chamber, and Mesa™ Processing Chamber, commercially available from Applied Materials, Inc., located in Santa Clara, California. It is contemplated that other processing chamber, including deposition chambers and those from other manufacturers, may be adapted to benefit from the disclosure.

The processing chamber 100 may be used for various plasma processes. In one example, the processing chamber 100 may be used to perform dry etching with one or more etching agents. In one example, a plasma is formed in the processing chamber from a processing gas, such as CₓF_{y} (where x and y can be different allowed combinations), O₂, NF₃, or combinations thereof.

The processing chamber 100 has a chamber body 113 and a system controller 126. The chamber body 113 includes a lid assembly 176, a support assembly 136 one or more sidewalls 122 and a chamber base 124, which collectively, with a chamber lid 123 of the lid assembly 176, define the processing volume 129. A substrate support assembly 180 is disposed in the processing volume 129.

The lid assembly 176 includes the chamber lid 123 and one or more plasma source assemblies, such as two inductively coupled plasma (ICP) assemblies 196, 197. Each ICP assembly 196, 197 includes a coil 181, 182, respectively, that is configured to inductively couple a radio frequency (RF) waveform generated by a RF generator 118 to a plasma 103 formed in the processing volume 129 of the processing chamber 100 during plasma processing. In this configuration, the chamber lid 123 includes a dielectric material that is configured to allow the fields generated by the coils 181, 182 during the delivery of an asymmetric voltage waveform by the RF generator 118 to help generate and sustain the plasma 103 in the processing volume 129.

The one or more sidewalls 122 and chamber base 124 generally include materials that are sized and shaped to form the structural support for the elements of the processing chamber 100 and are configured to withstand the pressures and added energy applied to them while the plasma 103 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy.

A gas inlet 128 is disposed through the chamber lid 123. The gas inlet 128 is used to deliver one or more processing gases to the processing volume 129 from a processing gas source 119. A substrate 101 is loaded into, and removed from, the processing volume 129 through an opening (not shown) formed through one of the sidewalls 122. The opening is sealed with a slit valve (also not shown) during plasma processing of the substrate 101.

A vacuum system 120 is coupled to the vacuum port 121. The vacuum system 120 may include a vacuum pump and a throttle valve (not shown). The throttle valve regulates the flow of gases through the processing chamber 100. The vacuum pump is coupled to the vacuum port 121 and configured to evacuate gases in the interior volume 108 through the vacuum port of the processing chamber 100.

The substrate support assembly 180, disposed in the processing volume 129, is configured to support the substrate 101 during processing. The substrate support assembly 180 may be coupled to a lift mechanism (not shown) through a shaft 138 which extends through the chamber base 124 of the chamber body 113. The lift mechanism may be flexibly sealed to the chamber body 113 by a bellows that prevents vacuum leakage around the shaft 138. The lift mechanism allows the substrate support assembly 180 to be moved vertically within the chamber body 113 between a lower substrate transfer position and one or more raised substrate processing positions.

One or more lift pins (not shown) may be disposed through the substrate support assembly 180. In one example, three or more lift pins extend through the substrate support assembly 180 such that the substrate 101 may be raised off a substrate supporting surface 105A of the substrate support assembly 180. The three or more lift pins may be activated by a lift ring (not shown) that is coupled to a lift ring actuator (not shown) that is configured to raise and lower the lift ring and three or more lift pins relative to the substrate supporting surface 105A.

The substrate support assembly 180 includes a substrate support 202. The substrate support 202 may be an electrostatic chuck (ESC). The substrate support 202 may include one or more lower electrodes. The one or more electrodes may be a capacitively coupled plasma (CCP) assembly configured to capacitively couple to a plasma source. Typically, the substrate support 202 is formed of a dielectric material, such as a bulk sintered ceramic material, such as a corrosion-resistant metal oxide or metal nitride material. Examples of suitable materials include aluminum oxide (Al₂O₃), aluminum nitride (AlN), titanium oxide (TiO), titanium nitride (TiN), yttrium oxide (Y₂O₃), mixtures thereof, or combinations thereof.

The substrate support 202 may include one or more heaters (not shown). The one or more heaters may be independently controllable. The one or more heaters enable the substrate support 202 to heat the substrate 101 from a bottom surface of the substrate 101 to a desired temperature. In one example, the substrate support 202 further includes a bias electrode 104 embedded in the dielectric material.

In one configuration, the bias electrode 104 is also used as a chucking pole used to secure (i.e., chuck) the substrate 101 to the substrate supporting surface 105A of the substrate support 202 and also to bias the substrate 101 with respect to the plasma 103 using one or more of the voltage waveform biasing schemes described herein. Typically, the bias electrode 104 is formed of one or more electrically conductive parts, such as one or more metal meshes, foils, plates, or combinations thereof.

The substrate support assembly 180 can additionally include a cooling base 204, a base plate 206 and a ground plate 112. The cooling base 204 is disposed on the base plate 206. The cooling base 204 is electrically isolated from the chamber base 124 by the base plate 206, and the ground plate 112 is interposed between the base plate 206 and the chamber base 124. The cooling base 204 may include a plurality of cooling channels (not shown) for circulating coolant therethrough. The cooling base 204 may be engaged with the substrate support 202 by a bond layer with an adhesive or by any other suitable mechanism.

A working surface 153 of the substrate support 202 is thermally coupled to and disposed a top surface 151 on the cooling base 204. The cooling base 204 has a cooling base outer diameter 192 which extends beyond a substrate support outer diameter 191 of the substrate support 202. For example, the cooling base outer diameter 192 is greater than the substrate support outer diameter 191. The RF powered insert ring 150 is disposed radially outward of the substrate support outer diameter 191 and is additionally, or partially, supported on the top surface 151 of the cooling base 204.

In some examples, the cooling base 204 is configured to regulate the temperature of the substrate support 202, and the substrate 101 disposed on the substrate support 202, during substrate processing. In some examples, the cooling base 204 is disposed on the base plate 206. The cooling base 204 may include a plurality of cooling channels (not shown) for circulating coolant therethrough. The cooling base 204 may be coupled to or engaged with the substrate support 202 by an adhesive or any suitable mechanism.

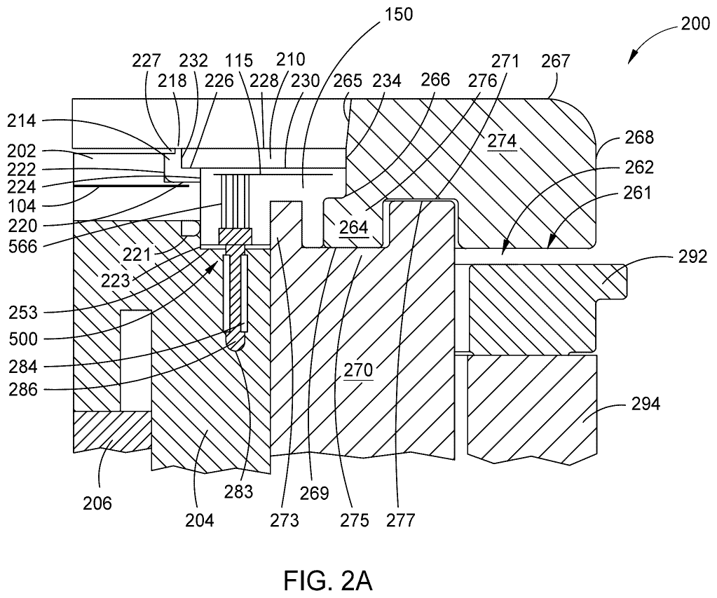

A process kit 200 is supported on the substrate support assembly 180. The process kit 200 includes an edge ring 210, a support ring 214 (Shown in FIGS. 2A and 2B), an outer ring 274 (Shown in FIGS. 2A and 2B) and the RF powered insert ring 150. The support ring 214 and the edge ring 210 are interfaced with each other such that edge ring 210 may be movable relative to support ring 214. The powered insert ring 150 is positioned to electrically couple to the edge ring 210

The processing chamber 100 may include a biasing assembly 299 that can include one or more plasma source assemblies that are each adapted to deliver an asymmetric voltage waveform to one or more electrodes and/or one or more coils disposed within the processing chamber 100. The one or more lower electrodes can include a bias electrode 104 and/or an edge electrode 115 that are disposed within the process kit 200, and are coupled to one or more plasma source assemblies, such as a waveform generation assembly. A first waveform generation assembly 208 may be coupled by a transmission line 157 to the bias electrode 104. In some examples, the first waveform generation assembly 208 is also electrically coupled through a conductive tube 167 to the edge electrode 115, which, as described further below, can include the powered insert ring 150. The waveform generation assembly 208 is configured to deliver a pulse voltage (PV) waveform generated by a PV waveform generator, such as PV waveform generator 208A to the plasma 103 formed in the processing volume 129 of the processing chamber 100 during plasma processing. In one example, the first PV waveform generator 208A of the first waveform generation assembly 208 is configured to bias both the bias electrode 104 and the edge electrode 115.

The PV waveform generator 208A is configured to deliver a plurality of asymmetric pulsed voltage waveforms to one or more electrodes within a plasma processing chamber to control and sustain a plasma formed in a processing region and/or control the formation of a sheath over the surface of a substrate during processing. The plasma processing methods and apparatus described herein are configured to improve the control of various characteristics of the generated plasma and control an ion energy distribution (IED) of the plasma generated ions that interact with one or more regions of a surface of a substrate during plasma processing. The ability to synchronize and control waveform characteristics, such as frequency, waveform shape and applied voltage on-time during a voltage waveform pulse provided in each of the pulsed voltage waveforms applied to the electrodes enables improved control of the generated plasma. As a result, greater precision for plasma processing can be achieved, which is described herein in more detail.

The biasing assembly 299 may also include a clamping network 209 so that a high voltage bias applied to the bias electrode 104 and/or edge electrode 115. In some examples, the bias electrode 104 is electrically coupled to a clamping network 209 and the edge electrode 115 is electrically coupled to a separate clamping network (not shown). The clamping network, by use of high voltage DC power source, provides a chucking voltage to the bias electrode 104 and/or edge electrode 115, such as a DC voltage between about −5000 V and about +5000 V.

In some examples, the edge electrode 115 is positioned below the edge of the substrate and is disposed a distance from a center of the bias electrode 104. In general, for a processing chamber 100 that is configured to process circular substrates, the edge electrode 115 is annular in shape, is made from a conductive material, and is configured to surround at least a portion of the bias electrode 104. For example, the edge electrode 115 may be formed from tungsten, molybdenum, cobalt, nickel, a combination of the one or more of the above, or other suitable material. In some examples, the edge electrode 115 is configured to surround at least a portion of the bias electrode 104 when viewed in a direction normal to the substrate supporting surface 105A. In one example, the powered insert ring 150 is positioned below the edge ring 210. In another example, the powered insert ring 150 includes a plurality of connected structures (e.g., pins, arc segments, etc.) that are configured to contact and support the edge ring 210.

In conventional processing chambers, a PV waveform generator is configured to provide a PV waveform to the chucking mesh (e.g., bias electrode) on substrate support. Unfortunately, the delivery of the PV waveform to the bias electrode is weakly coupled to the edge electrode in conventional systems. Thus, the process chamber 100 includes a biasing assembly 299 that is configured to provide improved delivery of a PV waveform to at least the electrodes disposed within the process kit 200, such as the bias electrode 104 and powered insert ring 150. In some configurations, the biasing assembly 299 is provided to overcome the weak DC coupling to the electrodes present in a plasma processing system.

In some examples, the PV waveform generator 208A is electrically coupled to the cooling base 204 through the conductive tube 167 that is electrically coupled to an output of the PV waveform generator 208A. In general, the PV waveform generator 208A is a voltage waveform generating power supply that is used to control the sheath formation over the surface of the substrate during plasma processing.

During processing, the PV waveform generator 208A of the biasing assembly 299 simultaneously couples the voltage waveform, such as pulsed voltage waveform, to both the bias electrode 104 in the substrate support 202 and the cooling base 204. The cooling base 204 is electro-mechanically coupled through a power coupling mechanism 500 (e.g., schematically shown in FIG. 2A) in the powered insert ring 150 to the edge electrode 115 disposed in the powered insert ring 150. The power coupling mechanism 500 can include an electrically conductive cable, wire, strap or other flexible element that is configured to transfer the generated voltage waveform provided from the PV waveform generator 208A to the edge electrode 115.

The system controller 126, also referred to herein as a processing chamber controller, operates to control the operations of processing chamber 100. For example, the system controller 126 may control the operations of the biasing assembly 299. The system controller 126 includes a central processing unit (CPU) 133, a memory 134, and support circuits 135. The system controller 126 is used to control the process sequence used to process the substrate 101, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing chamber 100. Typically, the software program, which is readable by CPU 133 in the system controller 126, includes code, which, when executed by the processor (CPU 133), performs tasks relating to the plasma processing methods described herein. The program may include instructions that are used to control the various hardware and electrical components within the processing chamber 100 to perform the various process tasks and various process sequences used to implement the methods described herein.

In one example, the system controller 126 controls the operations of the biasing assembly 299 to supply RF power to the powered insert ring 150. The process kit 200 having the powered insert ring 150 will now be discussed in greater detail with respect to FIGS. 2A and 2B. FIG. 2A is enlarged partial cross sectional view of a portion of the substrate support assembly 180 as shown in FIG. 1, according to one example. FIG. 2B is another enlarged partial cross sectional view of a portion of the substrate support assembly 180 of FIG. 1, according to one example.

The substrate support assembly 180 may have a plasma screen 292 and a liner 294. The plasma screen 292 is configured to limit the plasma 103 in the chamber to the processing volume 129. The liner 294 protects the substrate support assembly 180 below the plasma screen 292 from plasma 103 which passes through the plasma screen 292. In some examples, the liner 294 may additionally form part of a ground return path for the substrate support assembly 180.

As discussed above, the process kit 200 is supported on the substrate support assembly 180 and includes the edge ring 210, support ring 214, outer ring 274 and powered insert ring 150. The process kit 200 may additionally include a ceramic pipe 270. The ceramic pipe 270 is ring shaped having an inner diameter and an outer diameter. The inner diameter of the ceramic pipe 270 is sized to circumscribe the cooling base 204. The ceramic pipe 270 may be formed from quartz or other suitable material. The ceramic pipe 270 is fixedly disposed in the substrate support assembly 180 below the outer ring 274 and the insert ring 150. The ceramic pipe 270 has a top surface 271. A pipe channel 278 is formed through the top surface 271. The pipe channel 278 has a bottom 275 and separates the top surface 271 into an inner extension 273 and an outer extension 277.

The outer ring 274 rests on top of the ceramic pipe 270. The outer ring 274 is ring shaped and has an inner diameter 265, an outer diameter 268, a top surface 267 and a bottom surface 261. The bottom surface 261 has a channel 278 formed therein. The pipe channel 278 divides the bottom surface 261 into an outer protrusion 262 and an inner protrusion 264 along the inner diameter 265. A step 266 may be formed along the inner diameter 265. The step 266 results in a diameter of the inner diameter 256 at the inner protrusion 264 of the bottom surface 261 being less than a diameter of the inner diameter 256 at the top surface 267. The inner protrusion 264 extends into the pipe channel 278 of the ceramic pipe 270. When interfaced together, a bottom 276 of the pipe channel 278 rests against the outer extension 277 of the ceramic pipe 270. Additionally, a lower surface 269 of the inner protrusion 264 of the outer ring 274 is in contact with a bottom 275 of the pipe channel 278 of the ceramic pipe 270. In one or more examples, the inner protrusion 264 of the outer ring 274 does not extend the width of the pipe channel 278 formed in the ceramic pipe 270.

The support ring 214 and the edge ring 210 are interfaced with each other. The support ring 214 includes a top surface 218, a bottom surface 220, an inner edge 222, and an outer edge 224. The top surface 218 is substantially parallel to the bottom surface 220. The inner edge 222 is substantially parallel to the outer edge 224, and substantially perpendicular to the bottom surface 220. Generally, the height of the support ring 214 is limited by the height of the substrate support 202. For example, the inner edge 222 of the support ring 214 does not extend above the height of the substrate support 202. As such, the support ring 214 protects a side of the substrate support 202.

In some examples, the support ring 214 includes an outer stepped surface 226. In the example shown, the outer stepped surface 226 is formed in the outer edge 224, such that the outer stepped surface 226 is substantially parallel to the bottom surface 220. The outer stepped surface 226 defines a recess for receiving the edge ring 210. In some examples, the support ring 214 further includes an inner step surface 227. The inner step surface 227 is formed in the inner edge 222, such that the inner step surface 227 is substantially parallel to the bottom surface 220. The inner step surface 227 defines a recess for receiving the substrate 101. In some examples, the substrate 101, when positioned on the substrate supporting surface 105A of the substrate support 105, extends partially over the support ring 214 on the inner step surface 227.

The edge ring 210 has a ring body 216. The ring body 216 includes a top surface 228, a bottom surface 230, an inner edge 232, and an outer edge 234. The top surface 228 is substantially parallel to the bottom surface 230. The inner edge 232 is substantially parallel to the outer edge 234 and substantially perpendicular to the bottom surface 230. In one example, edge ring 210 is interfaced with the support ring 214 via the bottom surface 230. For example, the bottom surface 230 of edge ring 210 interfaces with the stepped surface 226 in the support ring 214. When interfaced with the support ring 214, the inner edge 232 of the edge ring 210 is spaced from the substrate 101. For example, the inner edge 232 of the edge ring 210 may be spaced between about 0.02 mm and about 0.1 mm from the substrate 101.

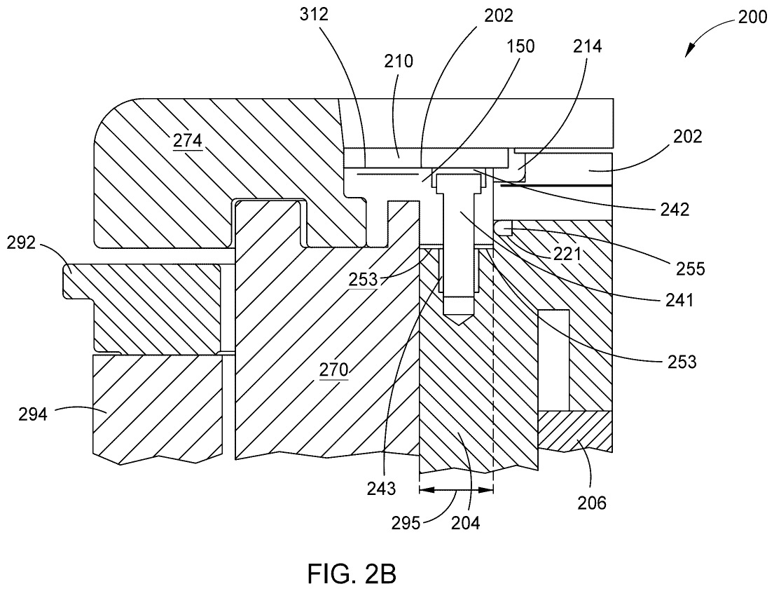

The powered insert ring 150 is disposed beneath the edge ring 210. The powered insert ring 150 is adjacent to, or circumscribes, the substrate support 202. Briefly turning to FIG. 3, FIG. 3 illustrates a top perspective view of the powered insert ring 150. The powered insert ring 150 is ring shaped and has an inner diameter 331, an outer diameter 333 and a center 399. The powered insert ring 150 has a top surface 312 and a bottom surface 314.

The powered insert ring 150 may be formed from a conductive material, such as a metal that can include aluminum, stainless steel, copper, or nickel, or other desirable conductive material. The powered insert ring 150 contacts the bottom surface 230 of the edge ring 210. Optionally, the powered insert ring 150 has a plurality of conductive pins (not shown). The conductive pins may extend above the top surface 312. In one example, the powered insert ring 150 has three conductive pins formed from silicon carbide (SiC). The conductive pin may enhance the source power conductance from the powered insert ring 150 to the edge ring 210. Alternatively, the top of the powered insert ring 150 may have a bare metal or thin layer of anodizing to make a flat contact with the edge ring 210 for improved conductivity between the powered insert ring 150 and the edge ring 210.

Returning to FIGS. 2A and 2B, the cooling base 204 extends beyond the substrate support 202 a distance 295. The distance 295 enables the powered insert ring 150 to additionally be disposed on and electrically coupled to the top surface 151 of the cooling base 204. In one example, one or more heat transfer shims 253 may additionally be disposed between the powered insert ring 150 and the cooling base 204. The heat transfer shims 253 enhance thermal coupling of the powered insert ring 150 to the cooling base 204. The cooling base 204 thermally couples to the powered insert ring 150 to manage the process kit temperature.

A slot 283 is formed in the cooling base 204 below the powered insert ring 150. In one example, the top surface 151 of the cooling base 204 has a first step 221 and a second step 223 formed therein at the outer diameter 192 of the cooling base 204. A bond seal 255 may be disposed in the first step 221. The bond seal 255 configured to protect a bond between the cooling base 204 and the substrate support 202. The second step 223 is positioned outward of the first step 221. In one example, the powered insert ring 150 may be disposed on the second step 223. The slot 283 is disposed in the second step 223 of the cooling base 204 and configured to engage the powered insert ring 150. For example, the cooling base 204 may multiple slots 283, such as three slots 283, for electrically coupling the cooling base 204 to the powered insert ring 150. Each slot 283 may have a contact terminal 284. The contact terminal 284 may be a metal spring or compression fitting suitable for securing a pin therein the slot 283 for making an electrical connection.

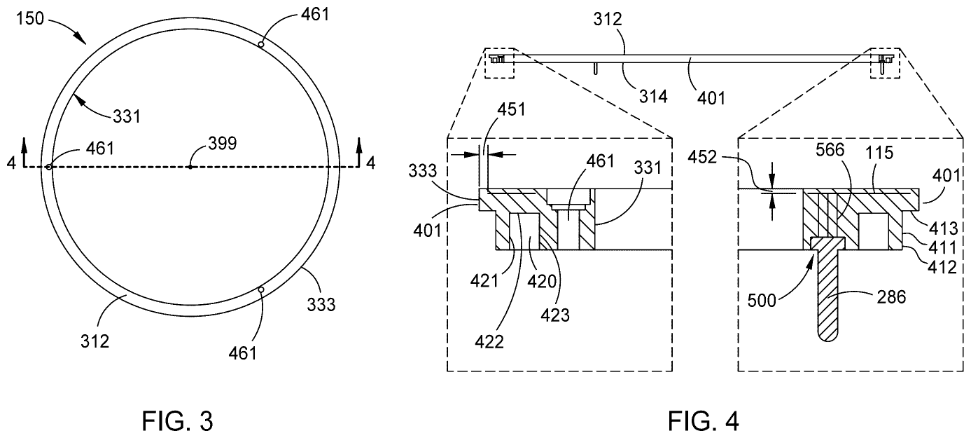

The powered insert ring 150 is coupled to the cooling base 204 by the power coupling mechanism 500. Turning briefly to FIG. 4, FIG. 4 illustrates a side perspective view of the powered insert ring 150. In one example, the power coupling mechanism 500 has a ring terminal, or pin 286. The pin 286 is electrically coupled to the edge electrode 155. In one example, the pin 286 is formed from tungsten, molybdenum, cobalt, nickel, a combination of the above or other suitably material. The pin 286 is couple to wires 566. The wires 566 may be metal filed vias or other suitable conductive pathways to the edge electrode 115.

The powered insert ring 150 has an upper outer wall 401 along the outer diameter 333. The edge electrode 115 may be a first distance 451 from the upper outer wall 401. For example, the edge electrode 115 may be a first distance 451 between about 1.0 mmm to about 1.5 mm from the upper outer wall 401. The edge electrode 115 may additionally be disposed a second distance 452 below the top surface 312 of the powered insert ring 150.

The powered insert ring 150 has a fastener opening 461 formed through the top surface 312 and the bottom surface 314. The fastener opening 461 may be shaped with to accept a bolt, screw or other fastener for affixing the powered insert ring 150 to the cooling base 204. In one example, the powered insert ring 150 has three fastener openings 461 for bolting the powered insert ring 150 to the cooling base 204. One or more bolts 241 are disposed in the fastener openings 461. The cooling base 204 may have a threaded insert 243. The bolts 241 thread into the threaded inserts 243 for securing the powered insert ring 150 to the cooling base 204. In one example, there are eight bolts 241 for securing the powered insert ring 150 to the cooling base 204. A ceramic screw cap 242 may be disposed about the head of the bolt 241. In one example, the screw cap 242 fills the fastener openings 461 to make the top surface 312 of the power insert ring 150 flush with the screw cap 242.

The powered insert ring 150 has an opening 420 formed in the bottom surface 314. The opening 420 may be rectangular shaped with sidewalls 421/423 and an inner bottom surface 422. The opening 420 is sized to accept the inner extension 273 of the ceramic pipe 270.

The powered insert ring 150 additionally has a recess portion 412 in the outer diameter 333. The outer diameter 333 has both a lower wall 411 and the upper outer wall 401. The lower wall 411 extends from a step 413 at the upper outer wall 401 to the bottom surface 314. That is, the lower wall 411 is farther away from the center 399 than the upper outer wall 401. The recess portion 412 may be rectangular shaped. The recess portion 412 is sized to accept the inner protrusion 264 of the outer ring 274. Additionally, both the inner protrusion 264 and lower wall 411 are configured to extend into the pipe channel 278 of the ceramic pipe 270.

The cooling base 204 has one or more contact terminals 284 disposed therein the slots 283. The pin 286 extends below the bottom surface 314 of the powered insert ring 150. The pin 286 is configured to extend into the slot 283 and make a connection with the contact terminal 284 creating an electrical connection between the power coupling mechanism 500 and the power to the cooling base 204. In another example, the pin 286 is equipped with the contact terminal 284 for making an electrical connection in the slot 283 with the cooling base 204. For example, the pin 286 may be hollow and have one or more sections that allow the pin 286 to compress. In either configuration/location disclosed above for the contact terminal 284, the contact terminal 284 allows the thermal cycling of the cooling base 204 and powered insert ring 150 without compromising the electrical connection or prevent breakage of the pin 286 while still enabling the powered insert ring 150 to be decoupled from the cooling base 204.

Advantageously, the power coupling mechanism provides a hard contact between the cathode, such as the cooling plate, and the power insert ring to provide sufficient DC voltage to the edge ring without moving parts for shaping plasma above a substrate for processing. The power coupling mechanism results in improved etch rate uniformity across a surface of a substrate by controlling the shape of a plasma sheath formed across the substrate during plasma processing, thereby increasing wafer processing yield. The processing chamber configuration includes a cooling plate in the substrate support configured as a cathode plate. The cooling plate has a threaded connection to the powered insert ring that is configured to enable the biasing of the edge ring during processing for adjusting the shape of the plasma sheath formed across the substrate. Thus, the new cathode configuration enables improved source power delivery to the edge ring with reduced particle contamination from component wear.

While the foregoing is directed to specific examples, other and further examples may be devised without departing from the basic scope thereof, and the scope thereof is determined by the claims that follow.

What is claimed is:

1. A process kit for a substrate support, the process kit comprising:
an edge ring having an inner diameter, a bottom surface and a top surface, the edge ring configured to circumscribe a substrate disposed on the substrate support; and
an insert ring positioned beneath the edge ring, the insert ring having an upper surface configured to contact the bottom surface of the edge ring, the insert ring comprising:
a body having a lower surface;
an electrode disposed in the body; and
a pin extending into the body through the lower surface and coupled to the electrode, wherein a conductive pin protrudes from the lower surface and is configured to couple to a power supply for the electrode.

2. The process kit of claim 1 further comprising:
a silicon carbide support ring comprising:
a support ring top surface, wherein the top surface of the edge ring extends above the support ring top surface;
a support ring outer diameter and a support ring inner diameter;
an outer step formed at the support ring top surface along the support ring outer diameter, the outer step configured to support the bottom surface of the edge ring along the support ring outer diameter; and
an inner step surface formed at the support ring top surface along the support ring inner diameter.

3. The process kit of claim 2, wherein the insert ring is radially outward of the silicon carbide support ring.

4. The process kit of claim 3 further comprising:
a heat transfer shim disposed on the lower surface of the insert ring.

5. The process kit of claim 1, wherein the insert ring has pins evenly spaced about the body of the insert ring.

6. The process kit of claim 5, wherein the conductive pin is coupled to the electrode by one of more via holes filled with metal.

7. The process kit of claim 6 wherein the body of the insert ring is formed from aluminum nitride.

8. A substrate support assembly comprising:
an electrostatic chuck (ESC) having an ESC outer diameter, a substrate supporting surface and a bottom surface;
a powered cooling base having a cooling base outer diameter and an upper surface, a slot formed in the upper surface of the powered cooling base near the cooling base outer diameter, the powered cooling base configured to be coupled to a power supply;
an edge ring having an inner diameter, a bottom surface and a top surface, the edge ring configured to circumscribe a substrate disposed on the ESC; and
an insert ring positioned beneath the edge ring, the insert ring having an upper surface configured to contact the bottom surface of the edge ring, the insert ring comprising:
a body having a lower surface;
an electrode disposed in the body; and
a pin extending into the body through the lower surface and coupled to the electrode, wherein a conductive pin of the pin protrudes from the lower surface and couples to power from the powered cooling base.

9. The substrate support assembly of claim 8 further comprising:
a silicon carbide support ring comprising:
a support ring top surface, wherein the top surface of the edge ring extends above the support ring top surface;
a support ring bottom surface disposed on the ESC,
a support ring outer diameter and a support ring inner diameter, wherein the support ring is disposed along the ESC outer diameter;
an outer step formed at the support ring top surface along the support ring outer diameter, the outer step configured to support the bottom surface of the edge ring along the support ring outer diameter; and
an inner step surface formed at the support ring top surface along the support ring inner diameter.

10. The substrate support assembly of claim 8 further comprising:
a silicon carbide support ring disposed on the ESC and supporting the edge ring, wherein the insert ring is radially outward of the silicon carbide support ring.

11. The substrate support assembly of claim 10 further comprising:
a heat transfer shim disposed on the lower surface of the insert ring.

12. The substrate support assembly of claim 11, wherein the body of the insert ring is formed from aluminum nitride and the insert ring has pins evenly spaced about the body of the insert ring.

13. The substrate support assembly of claim 12, wherein the conductive pin is coupled to the electrode by one of more via holes filled with metal.

14. A substrate processing chamber comprising:
a chamber body comprising:
a lid assembly;
one or more sidewalls; and
a chamber base, the lid assembly, the one or more sidewalls and the chamber base collectively defining a processing volume; and
a substrate support assembly disposed in the processing volume; the substrate support assembly comprising:
an electrostatic chuck (ESC) having an ESC outer diameter, a substrate supporting surface and a bottom surface;
a powered cooling base having a cooling base outer diameter and an upper surface, a slot formed in the upper surface of the powered cooling base near the cooling base outer diameter, the powered cooling base configured to be coupled to a power supply;
an edge ring having an inner diameter, a bottom surface and a top surface, the edge ring configured to circumscribe a substrate disposed on the ESC; and
a insert ring positioned beneath the edge ring, the insert ring having an upper surface configured to contact the bottom surface of the edge ring, the insert ring comprising:
a body having a lower surface;
an electrode disposed in the body; and
an pin extending into the body through the lower surface and coupled to the electrode, wherein a conductive pin of the pin protrudes from the lower surface and couples to power from the powered cooling base.

15. The substrate processing chamber of claim 14 further comprising:
a silicon carbide support ring comprising:
a support ring top surface, wherein the top surface of the edge ring extends above the support ring top surface;
a support ring bottom surface disposed on the ESC,
a support ring outer diameter and a support ring inner diameter, wherein the support ring is disposed along the ESC outer diameter;
an outer step formed at the support ring top surface along the support ring outer diameter, the outer step configured to support the bottom surface of the edge ring along the support ring outer diameter; and
an inner step surface formed at the support ring top surface along the support ring inner diameter.

16. The substrate processing chamber of claim 14 further comprising:
a silicon carbide support ring disposed on the ESC and supporting the edge ring, wherein the insert ring is radially outward of the silicon carbide support ring.

17. The substrate processing chamber of claim 16 further comprising:
a heat transfer shim disposed on the lower surface of the insert ring.

18. The substrate processing chamber of claim 17, wherein the body of the insert ring is formed from aluminum nitride and the insert ring has pins evenly spaced about the body of the insert ring.

19. The substrate processing chamber of claim 18, wherein the conductive pin is coupled to the electrode by metal disposed in one of more via holes.

20. The substrate processing chamber of claim 14, wherein the insert ring further comprises:
vias filled with metal connecting the electrode to conductive pin.
